(19) United States
(12) Patent Application Publication
(10) Pub. No.: US 2026/0106444 A1
(43) Pub. Date: Apr. 16, 2026

(54) ELECTRONIC FUSE DEVICE

(71) Applicant: HELLA GMBH & CO. KGAA, Lippstadt (DE)

(72) Inventors: Daniel Klimeck, Bad Wünnenberg (DE); Christopher Lankeit, Paderborn (DE); Niklas May-Johann, Lippstadt (DE)

(21) Appl. No.: 19/353,073

(22) Filed: Oct. 8, 2025

(30) Foreign Application Priority Data
Oct. 11, 2024 (DE) 102024129411.6

(51) Int. Cl. H02H 3/08; H03K 17/082; H03K 17/18

(52) U.S. Cl. CPC H02H 3/08; H03K 17/082; H03K 17/18

(57) ABSTRACT

The present invention relates to an electronic fuse device. The electronic fuse device includes: a semiconductor switch and a current monitoring unit. The current monitoring unit is configured to continuously detect a load current flowing through the semiconductor switch during operation and to determine a load current value indicating the load current. The current monitoring unit includes a filter unit for filtering a detection signal detected by the current monitoring unit, and the current monitoring unit includes a correction unit which is configured to determine a measure of dispersion of the load current value and to carry out a correction of the load current value based on the determined measure of dispersion.

### CROSS-REFERENCE TO RELATED APPLICATIONS

The present application claims the benefit of German Patent Application 10-2024-129-411.6, filed Oct. 11, 2024, the disclosure of which is incorporated by reference.

### BACKGROUND OF THE INVENTION

The present invention relates to an electronic fuse device including: a semiconductor switch, and a current monitoring unit which is configured to continuously detect a load current flowing through the semiconductor switch during operation and to determine a load current value indicating the load current, wherein the current monitoring unit includes a filter unit for filtering a detection signal detected by the current monitoring unit.

Such an electronic fuse device is known, for example, from DE 10-2020-127-040 A1. The present invention is based on the object of realizing an electronic fuse device that can reliably prevent an overcurrent at a connected electrical load.

### SUMMARY OF THE INVENTION

According to the invention, the foregoing object is achieved by an electronic fuse device as set forth herein. The electronic fuse device according to the invention includes at least one semiconductor switch which is designed to be connected on the input side to an electrical power source, in particular a motor vehicle battery and/or a motor vehicle DC/DC converter, and on the output side to the electrical load to be fused. The semiconductor switch is preferably a so-called power semiconductor switch. Preferably, the semiconductor switch comprises at least one, preferably several so-called MOSFETs (metal-oxide-semiconductor field-effect transistors) connected electrically in parallel. However, it is also conceivable that the semiconductor switch comprises one or more so-called IGBTs (insulated gate bipolar transistors), one or more JFETs (junction field effect transistors), one or more BJTs (bipolar junction transistors) or one or more HEMTs (high electron mobility transistors).

The electronic fuse device according to the invention comprises a current monitoring unit which is configured in a known manner, for example by means of a measuring resistor and a suitable measuring circuit, to continuously detect a load current currently flowing through the semiconductor switch, in particular through a so-called load current path of the semiconductor switch, during operation. The current monitoring unit is also configured in a known manner to determine a digital load current value indicating the load current currently flowing through the semiconductor switch. The current monitoring unit typically comprises a so-called analog-to-digital converter (ADC), which is provided with an analog signal and outputs a digital signal, i.e. a digital data stream. The ADC may be a separate component or may be integrated with other electrical/electronic components in a single component, such as an ASIC or a microcontroller.

In order to avoid so-called aliasing effects, the current monitoring unit comprises a filter unit designed in a known manner for filtering a detection signal detected by the current monitoring unit. The filter unit is configured to filter out signal components above a cut-off frequency, i.e. to perform either low-pass filtering or band-pass filtering, wherein the cut-off frequency is preferably determined taking into account the so-called Nyquist-Shannon sampling theorem. The filter unit is preferably designed as an analog filter, but can in principle also be designed as a digital filter.

As signal components above the cut-off frequency are filtered out by the filter unit, a load current value determined based on the filtered detection signal will tend to indicate a load current that is too low, with the deviation between the load current indicated by the load current value and the load current actually flowing through the semiconductor switch being greater the more or the more pronounced high-frequency current peaks the load current actually flowing through the semiconductor switch has.

According to the invention, the current monitoring unit therefore comprises a correction unit which is configured to determine a measure of dispersion of the load current value and to perform a correction of the load current value based on the determined measure of dispersion. In statistics, measures of dispersion, also called dispersion measures or dispersion parameters, comprise various measures that describe the dispersion width of observed values, in this case the dispersion width of the load current, around a suitable position parameter. Known measures of dispersion are, for example, the so-called variance or the so-called standard deviation. A high measure of dispersion of the determined load current value is an indicator that the load current actually flowing through the semiconductor switch has many or pronounced high-frequency current peaks, and thus is an indicator of a pronounced underestimation of the load current actually flowing through the semiconductor switch by the determined load current value. The size of the measure of dispersion is therefore a good indicator of when or how much the determined load current value needs to be corrected in order to obtain a load current value that is as accurate as possible.

The correction unit according to the invention thus makes it possible to determine a particularly accurate load current value, thereby in turn making it possible to realize an electronic fuse device that can reliably prevent an overcurrent at a connected electrical load.

Preferably, the correction unit is configured to compare the determined measure of dispersion with a threshold value and to only correct the load current value if the determined measure of dispersion exceeds the threshold value. The correction of the load current value is therefore only carried out if the measure of dispersion indicates a significant underestimation of the load current actually flowing through the semiconductor switch, i.e. only if a significant improvement can be expected as a result of the correction. This makes it possible to determine an accurate load current value in a relatively simple and resource-saving way.

In principle, the correction unit can be configured to carry out any type of correction, i.e. adjustment, of the previously determined load current value. For example, it is conceivable in principle that the correction unit is configured to perform a complex model-guided or map-guided correction of the previously determined load current value. Preferably, however, the correction unit is configured to offset the previously determined load current value against a correction value in a simple manner in order to carry out the correction. This makes it possible to determine an accurate load current value in a relatively simple and resource-saving way. The correction value can, for example, be added to the previously determined load current value or multiplied by the previously determined load current value.

Here, the correction value can in principle be either constant or variable. The correction unit is particularly preferably configured to determine the correction value based on the previously determined load current value and/or the measure of dispersion. Typically, the correction unit is configured to determine a larger correction value the larger the load current value or the measure of dispersion is. For example, the correction unit can be configured to set the correction value equal to the previously determined load current value in order to square the previously determined load current value to perform the correction. This makes it possible to determine a particularly accurate load current value.

In a preferred embodiment, the electronic fuse device according to the invention comprises a computing unit, preferably a microcontroller, wherein the correction unit is realized by suitable programming of the computing unit, i.e. software-based. This makes it possible to easily optimize the correction unit for different applications by adapting the programming of the computing unit. Furthermore, the software-based correction unit can also be readjusted relatively easily, if necessary, by adapting the programming of the computing unit.

Preferably, the filter unit comprises a hardware-based filter circuit designed in a fundamentally known manner for filtering an analog detection signal.

In a preferred embodiment, the electronic fuse device according to the invention additionally comprises at least one further semiconductor switch. In this case, the current monitoring unit is configured to continuously detect a load current flowing through the respective semiconductor switch for each semiconductor switch during operation and to determine a load current value indicating the respective load current. Furthermore, in this case, the correction unit is configured to determine a measure of dispersion of the load current value for each semiconductor switch and to carry out a correction of the respective load current value based on the determined measure of dispersion. This makes it possible to realize an electronic fuse device that can reliably prevent an overcurrent on several electrical loads, each connected to one of the semiconductor switches.

### BRIEF DESCRIPTION OF THE DRAWINGS

An exemplary embodiment of the present invention is described below with reference to the accompanying figures. In the figures:

FIG. 1 is a schematic diagram of an electronic fuse device according to the invention; and

FIG. 2 is a schematic diagram of a current monitoring unit of the electronic fuse device from FIG. 1.

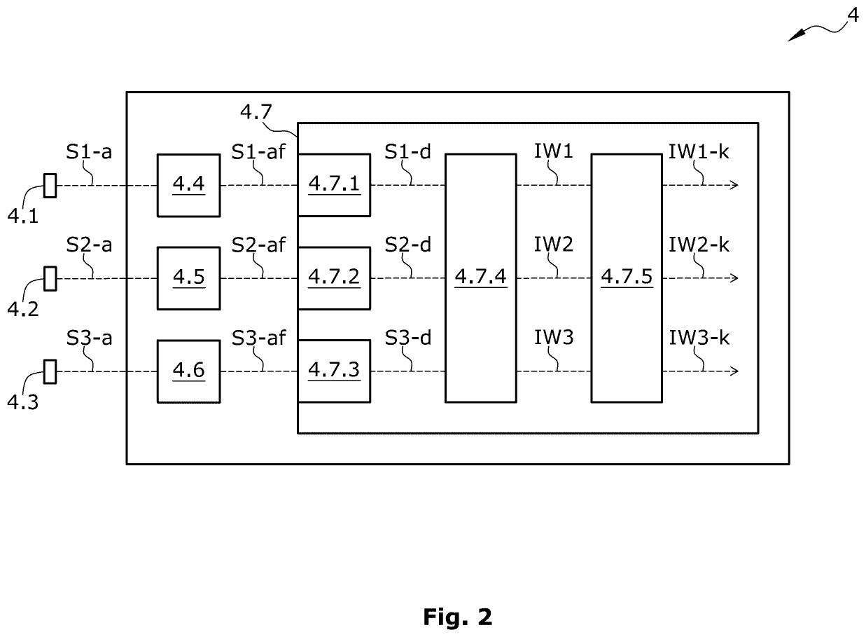

### DETAILED DESCRIPTION OF THE CURRENT EMBODIMENTS

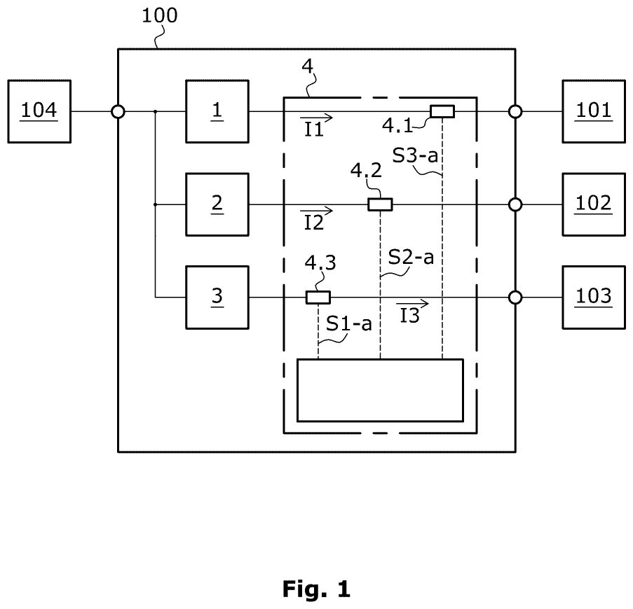

FIG. 1 shows an electronic fuse device 100 according to the invention, which in the present exemplary embodiment comprises three semiconductor switches 1, 2, 3 and is thus designed in the present exemplary embodiment to fuse three electrical loads 101, 102, 103, wherein the electronic fuse device 100 could in principle also have any other number of semiconductor switches for fusing a corresponding number of electrical loads.

All three semiconductor switches 1, 2, 3 are each electrically connected on the input side to an electrical energy source 104.

The first semiconductor switch 1 is electrically connected on the output side to the first load 101, the second semiconductor switch 2 is electrically connected on the output side to the second load 102, and the third semiconductor switch 3 is electrically connected on the output side to the third load 103.

The electronic fuse device 100 also comprises a current monitoring unit 4.

The current monitoring unit 4 comprises first measuring means 4.1 for detecting a first load current I1 flowing through the first semiconductor switch 1 during operation, second measuring means 4.2 for detecting a second load current I2 flowing through the second semiconductor switch 2 during operation, and third measuring means 4.3 for detecting a third load current I3 flowing through the third semiconductor switch 3 during operation.

The current monitoring unit 4 comprises a first filter unit 4.4 for filtering a first analog detection signal S1-a detected by the first measuring means 4.1, a second filter unit 4.5 for filtering a second analog detection signal S2-a detected by the second measuring means 4.2, and a third filter unit 4.6 for filtering a third analog detection signal S3-a detected by the third measuring means 4.3.

The three filter units 4.4, 4.5, 4.6 each comprise a hardware-based filter circuit not shown here.

The current monitoring unit 4 comprises a computing unit 4.7 in the form of a microcontroller, to which the analog detection signals S1-af, S2-af, S3-af filtered by the filter units 4.4, 4.5, 4.6 are provided.

The computing unit 4.7 comprises a first analog-to-digital converter 4.7.1 for converting a first filtered analog detection signal S1-af provided by the first filter unit 4.4 into a first digital detection signal S1-d, a second analog-to-digital converter 4.7.2 for converting a second filtered analog detection signal S2-af provided by the second filter unit 4.5 into a second digital detection signal S2-d, and a third analog-to-digital converter 4.7.3 for converting a third filtered analog detection signal S3-af provided by the third filter unit 4.6 into a third digital detection signal S3-d.

The computing unit 4.7 comprises a software-based evaluation unit 4.7.4, i.e. realized by suitable programming of the computing unit 4.7, to which the digital detection signals S1-d, S2-d, S3-d are provided.

The evaluation unit 4.7.4 is configured to continuously determine a first load current value IW1 indicating the first load current I1 based on the first digital detection signal S1-d, to continuously determine a second load current value IW2 indicating the second load current I2 based on the second digital detection signal S2-d, and to continuously determine a third load current value IW3 indicating the third load current I3 based on the third digital detection signal S3-d.

The computing unit 4.7 comprises a software-based correction unit 4.7.5, i.e. realized by suitable programming of the computing unit 4.7, to which the load current values IW1, IW2, IW3 determined by the evaluation unit 4.7.4 are provided.

The correction unit 4.7.5 is configured to individually determine a measure of dispersion, for example the variance, for each of the load current values IW1, IW2, IW3 and to compare the determined measure of dispersion with a threshold value.

The correction unit 4.7.5 is further configured to perform a correction of the respective load current value IW1, IW2, IW3 based on the respective determined measure of dispersion if the determined measure of dispersion is greater than the threshold value in order to determine corrected load current values IW1-k, IW2-k, IW3-k.

In particular, the correction unit 4.7.5 is configured to determine a correction factor based on the respective measure of dispersion determined and/or based on the respective load current value IW1, IW2, IW3 in order to carry out the correction, i.e. to determine the corrected load current values IW1-k, IW2-k, IW3-k, and to offset, for example multiply, the correction factor determined by the load current value IW1, IW2, IW3 to be corrected.

### LIST OF REFERENCE SYMBOLS

100 electronic fuse device
1 first semiconductor switch
2 second semiconductor switch
3 third semiconductor switch
4 monitoring unit
4.1 first measuring means
4.2 second measuring means
4.3 third measuring means
4.4 first filter unit
4.5 second filter unit
4.6 third filter unit
4.7 computing unit
4.7.1 first analog-to-digital converter
4.7.2 second analog-to-digital converter
4.7.3 third analog-to-digital converter
4.7.4 evaluation unit
4.7.5 correction unit
101 first electrical load
102 second electrical load
103 third electrical load
104 electrical power source
I1 first load current
IW1 first load current value
IW1-k first corrected load current value
I2 second load current
IW2 second load current value
IW2-k second corrected load current value
I3 third load current
IW3 third load current value
IW3-k third corrected load current value
S1-a first analog detection signal
S1-af first filtered analog detection signal
S1-d first digital detection signal
S2-a second analog detection signal
S2-af second filtered analog detection signal
S2-d second digital detection signal
S3-a third analog detection signal
S3-af third filtered analog detection signal
S3-d Third Digital Detection Signal

The above description is that of a current embodiment of the invention. Various alterations and changes can be made without departing from the spirit and broader aspects of the invention. This disclosure is presented for illustrative purposes and should not be interpreted as an exhaustive description of all embodiments of the invention or to limit the scope of the claims to the specific elements illustrated or described in connection with these embodiments. Any reference to elements in the singular, for example, using the articles “a,” “an,” “the,” or “said,” is not to be construed as limiting the element to the singular.

1. An electronic fuse device comprising:
a semiconductor switch; and
a current monitoring unit which is configured to continuously detect a load current flowing through the semiconductor switch during operation and to determine a load current value indicative of the load current, wherein the current monitoring unit includes:
a filter unit for filtering a detection signal detected by the current monitoring unit, and
a correction unit which is configured to determine a measure of dispersion of the load current value and which is configured to carry out a correction of the load current value based on the determined measure of dispersion.

2. The electronic fuse device of claim 1, wherein the correction unit is further configured to compare the determined measure of dispersion with a threshold value and configured to carry out the correction of the load current value only if the determined measure of dispersion exceeds the threshold value.

3. The electronic fuse device of claim 1, wherein the correction unit is further configured to offset the load current value against a correction value in order to carry out the correction.

4. The electronic fuse device of claim 3, wherein the correction unit is configured to determine the correction value based on the load current value or the measure of dispersion.

5. The electronic fuse device of claim 1, further comprising a computing unit, wherein the computing unit includes the correction unit therein.

6. The electronic fuse device of claim 1, wherein the filter unit comprises a hardware-based filter circuit.

7. The electronic fuse device of claim 1, wherein the semiconductor switch as a first semiconductor switch, electronic fuse device further comprising a second semiconductor switch,
wherein the current monitoring unit is configured to continuously detect a load current flowing through the second semiconductor switch during operation and determine a load current value indicating the load current flowing through the second semiconductor switch, and
wherein the correction unit is further configured to determine a measure of dispersion of the load current value for the second semiconductor switch and configured to carry out a correction of the load current value for the second semiconductor switch based on the determined measure of dispersion for the second semiconductor switch.
